(19) United States
(12) Patent Application Publication
(10) Pub. No.: US 2012/0192848 A1
(43) Pub. Date: Aug. 2, 2012

(54) METHOD OF SLICING SILICON INGOT USING WIRE SAW AND WIRE SAW

(76) Inventors: Akira Nakashima, Minato-ku (JP); Yukinobu Kaiga, Minato-ku (JP)

(21) Appl. No.: 13/499,990

(22) PCT Filed: Sep. 13, 2010
(86) PCT No.: PCT/JP10/66119

§ 371 Date: Apr. 3, 2012

(30) Foreign Application Priority Data
Oct. 7, 2009 (JP) 2009-233571

(51) Int. Cl. H01L 21/304; B28D 5/04

(52) U.S. Cl. 125/21

(57) ABSTRACT

To provide a method of slicing a silicon ingot for slicing a silicon ingot using a bonded abrasive wire saw, which can reduce the consumption of the bonded abrasive wire required for the slicing process as much as possible, thereby greatly reducing the manufacturing cost and to provide a wire saw used for this method. In the method of slicing a silicon ingot using a wire saw, while a bonded abrasive wire helically wound at a constant pitch around peripheral surfaces of a plurality of rollers is run with a coolant being supplied onto the wire, and while the coolant is also supplied to a side portion of the silicon ingot to be cut where the wire passes in slicing of the silicon ingot; the silicon ingot is moved relative to the wire, thereby slicing the silicon ingot to form a plurality of silicon wafers.

### TECHNICAL FIELD

The present invention relates to a slicing method for manufacturing silicon wafers by slicing a silicon ingot using a wire saw provided with a bonded abrasive wire, and to the wire saw.

### RELATED ART

A wire saw is a slicing machine for slicing a work (silicon ingot), that includes a wire array formed by helically winding a wire at a constant pitch around a plurality of rollers. With the wire saw, the work is sliced by running the wire while supplying a working fluid and pressing the work against the wire array. Such wire saws can simultaneously cut many wafers out of a work; therefore, they have been widely used in a process for slicing silicon ingots to produce silicon wafers.

FIG. 6 is a schematic diagram of a main part of a typical wire saw. A wire saw 10 includes a wire supply and take-up means (not shown) for supplying and taking up a wire 20, main rollers 30 spaced a predetermined distance from each other in parallel, nozzles 40 for supplying a coolant to the main rollers 30, and nozzles 50 for supplying a working fluid to the wire 20. A plurality of grooves are formed at a constant pitch on surfaces of the main rollers 30, and the wire 20 is wound on those grooves to form a wire array. Above the wire array, a work holder 60 for retaining a work W and pressing the work W against the wire array is disposed so that it can be moved up and down using an elevating unit not shown.

The wire 20 is run by the wire supply and take-up means, and the working fluid is supplied from the nozzles 50 to the wire 20 being run. Meanwhile, the work holder 60 retaining the work W is moved down by the elevating unit to press the work W against the wire 20 in the wire array. Thus, the work W is sliced. Note that in slicing, the main roller 30 is cooled by the liquid coolant supplied from the nozzles 40.

Such wire saws described above are broadly classified into two types: free abrasive wire saws and bonded abrasive wire saws. For slicing silicon ingots, in general, free abrasive wire saws are widely used. A free abrasive wire saw uses a slurry containing abrasive grains as a working fluid, and a wire is run while the slurry is continuously supplied to the wire. The work is sliced by grinding action of the slurry fed, by the run of the wire, to a portion of the work to be cut. Thus, use of a free abrasive wire saw makes it possible to perform a slicing process for obtaining a large number of wafers at a time. Accordingly, the productivity has been significantly improved as compared with conventional slicing processes using inner diameter blade saws.

However, slicing processes of silicon ingots using free abrasive wire saws have problems resulting from use of slurry as a working fluid. For example, since a working fluid is attached to wafers obtained by the slicing process, the working fluid is removed in a subsequent cleaning process; however, when the working fluid attached to the wafers is slurry, the removal requires much labor. Further, the working fluid supplied at the time of slicing is scattered to adhere to the wire saw machine or a workplace around the machine; therefore, a working fluid of slurry makes it difficult to perform cleaning to remove the deposit. Moreover, a free abrasive wire saw utilizes grinding action of abrasive grains contained in slurry to perform a slicing process; thus, the slicing speed is lower than in cases of using conventional inner diameter blade saws.

As a solution to the above problems, in recent years, a technique of slicing silicon ingots using a bonded abrasive wire saw is attracting attention. A bonded abrasive wire saw includes a wire with abrasive grains fixed to a surface of the wire along its entire length. Specifically, a bonded abrasive wire saw performs a slicing process of a work utilizing grinding action of the abrasive grains fixed to the wire surface, which allows a working fluid (coolant) containing no abrasive grains to be used. This solves the problems resulted from slurry in cases of using free abrasive wire saws. A technique of slicing a silicon ingot using such a bonded abrasive wire saw is disclosed, for example, in Patent Document 1.

### PRIOR ART DOCUMENT

### Patent Document

Patent Document 1: JP 2000-288902 A

The technique of slicing a silicon ingot using a bonded abrasive wire saw makes it possible to simplify a subsequent wafer cleaning process and to reduce the slicing time, so that the production efficiency is greatly improved. However, the biggest problem in using a bonded abrasive wire saw is the high cost. Abrasive grains in a surface of a bonded abrasive wire are worn out and lost after repeated use, which results in impaired working performance. Further, working performance would also be impaired when the surface with abrasive grains is clogged with machining dust generated by a slicing process. A bonded abrasive wire is therefore required to be replaced after a certain period of use; however, a bonded abrasive wire with abrasive grains fixed to its surface is very expensive as much as approximately 200 times the unit price of the wire used for a free abrasive wire saw.

Therefore, the following is absolutely required in order to reduce the manufacturing cost in the case of using a bonded abrasive wire saw for slicing silicon ingots to a level comparable with that in the case of using a free abrasive wire saw. Abrasive grains fixed to the surface of a bonded abrasive wire should be prevented from being worn out or lost, and clogging due to machining dust should be prevented. Thus, the life of the bonded abrasive wire should be prolonged, and the amount of wire consumed should be reduced as much as possible. Despite that, prevention of abrasive grains from being worn out and lost is not considered at all in Patent Document 1 above, and the cost issues remain unresolved.

### DISCLOSURE OF THE INVENTION

### Problems to be Solved by the Invention

The present invention has been developed in view of the above circumstances. It is an object of the present invention to provide a method of slicing a silicon ingot, in which the silicon ingot is sliced using a bonded abrasive wire saw, and at that time, abrasive grains fixed to a surface of a bonded abrasive wire is prevented from being worn out or lost and clogging due to machining dust is prevented. This method can reduce the consumption of the bonded abrasive wire required for the slicing process as much as possible; thus, the manufacturing cost can be greatly reduced. It is another object of the present invention to provide a wire saw used for this method.

### Means for Solving the Problem

The inventors of the present invention have researched the causes of wear and loss of abrasive grains fixed to a surface of a bonded abrasive wire and clogging due to machining dust in slicing a silicon ingot using the bonded abrasive wire saw, and they made extensive studies to find a method for preventing such phenomena.

In general, a working fluid (coolant) used for a bonded abrasive wire saw has lower viscosity as compared with a working fluid (slurry) used for a free abrasive wire saw, so that the working fluid (coolant) supplied in a slicing process is difficult to be retained on a wire. Therefore, when a silicon ingot is sliced using a bonded abrasive wire saw having a typical structure shown in FIG. 6, most of the working fluid (coolant) supplied to the wire by nozzles 50 falls from the wire before reaching the portion to be cut, which makes it impossible to ensure sufficient amount of the working fluid (coolant) to be supplied to the portion to be cut. If the slicing process of a silicon ingot is performed under such circumstances, processing heat on the portion to be sliced cannot be suppressed sufficiently. The inventors have found that this processing heat leads to change in properties of abrasive grains fixed to a surface of the bonded abrasive wire and to reduced durability thereof, which results in wear and loss of the abrasive grains.

The inventors further found the following facts. The working fluid (coolant) supplied to a portion to be cut also acts to propel and expel machining dust generated in a slicing process from a portion to be cut and a wire; however, when the amount of the working fluid (coolant) supplied to the portion to be cut is not enough, the above expelling action is not sufficient. Accordingly, machining dust adheres to the wire and clogging is caused.

Based on the above knowledge, the inventors succeeded in developing a technique of slicing silicon ingots that enables the following features. In slicing a silicon ingot using a bonded abrasive wire saw, a method of supplying a working fluid (coolant) used for the slicing process is optimized to ensure sufficient amount of working fluid (coolant) supplied to a portion of the silicon ingot to be cut, and in addition, the viscosity of the above working fluid (coolant) is specified to effectively inhibit wear and loss of abrasive grains and clogging, so that the product yield can be improved. Thus, the present invention has been completed.

The present invention primarily includes the following constituent features.

(1) A method of slicing a silicon ingot using a wire saw, wherein while a bonded abrasive wire helically wound at a constant pitch around peripheral surfaces of a plurality of rollers is run with a coolant being supplied onto the wire, and while the coolant is also supplied to a side portion of the silicon ingot to be cut where the wire passes in slicing of the silicon ingot; the silicon ingot is moved relative to the wire, thereby slicing the silicon ingot to form a plurality of silicon wafers.

(2) The method of slicing a silicon ingot according to (1) above, wherein the coolant has a viscosity of 0.1 mPa·s or more and 100 mPa·s or less.

(3) A wire saw comprising: a bonded abrasive wire helically wound at a constant pitch around peripheral surfaces of a plurality of rollers; a first coolant supply means for supplying a coolant onto the wire; and a second coolant supply means provided with a guide board for guiding the coolant to a side portion of the silicon ingot to be cut where the wire passes in slicing of the silicon ingot.

### Effect of the Invention

According to the present invention, in slicing a silicon ingot using a bonded abrasive wire saw, the consumption of the bonded abrasive wire required for the slicing process can be reduced as much as possible. Therefore, the present invention is extremely useful in increasing the efficiency of a silicon wafer production process and reducing the cost.

### BRIEF DESCRIPTION OF THE DRAWINGS

FIG. 1 is a schematic diagram of a main part of a wire saw of the present invention in a state where a silicon ingot is being sliced.

FIG. 2 is a graph showing the amount of deflection of a wire in Example 1.

FIG. 3 is a micrograph showing a surface condition of a wire having been used in Example 1 (observed by SEM).

FIG. 4 is a graph showing the amount of deflection of a wire in Comparative Example 1.

FIG. 5 is a micrograph showing a surface condition of a wire having been used in Comparative Example 1 (observed by SEM).

FIG. 6 is a schematic diagram of a main part of a typical wire saw in a state where a silicon ingot is being sliced.

### BEST MODE FOR CARRYING OUT THE INVENTION

The present invention will be described below in detail.

In a method of slicing a silicon ingot using a wire saw in accordance with the present invention, while a bonded abrasive wire helically wound at a constant pitch around peripheral surfaces of a plurality of rollers is run with a coolant being supplied onto the wire, and while the coolant is also supplied to a side portion of the silicon ingot to be cut where the wire passes in slicing of the silicon ingot; the silicon ingot is moved relative to the wire, thereby slicing the silicon ingot to form a plurality of silicon wafers.

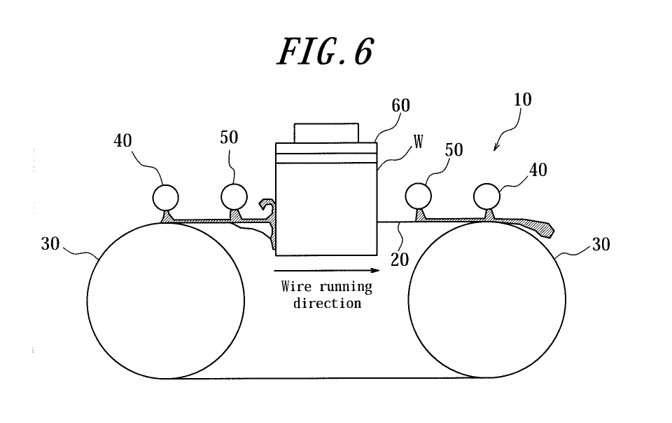

As described above, the present invention is the same as the conventional technique shown in FIG. 6 in that a wire array is formed by helically winding a bonded abrasive wire (hereinafter simply referred to as a wire) at a constant pitch around a plurality of rollers, and a silicon ingot is sliced by running the wire while supplying a coolant, that is a working fluid, and pressing the silicon ingot against the wire array (in other words, the silicon ingot is moved relative to the wire). However, the present invention is greatly different from the conventional technique in that the coolant is also supplied to a side portion of the silicon ingot to be cut where the wire passes in slicing of the silicon ingot.

In the present invention, the coolant is supplied to the side portion of the silicon ingot to be cut where the wire passes in slicing of the silicon ingot, so that the coolant can be sufficiently supplied to a portion of the silicon ingot to be sliced. Therefore, processing heat due to insufficient coolant supply that causes wear and loss of abrasive grains fixed to the wire surface can be sufficiently suppressed.

Further, in a conventional technique shown in FIG. 6, coolant is hardly supplied to a portion of a silicon ingot to be sliced particularly on the side where the wire to be run is wound out, which makes the wire surface be easily clogged with machining dust. To the contrary, in the present invention, coolant is ensured to be also supplied to side portions of a silicon ingot to be cut where the wire passes in slicing of the silicon ingot. Accordingly, the coolant is also supplied to a portion of the silicon ingot to be sliced on the side where the wire to be run is wound out. Therefore, the present invention is significantly advantageous as a method of inhibiting the clogging caused in the conventional technique.

Note that a wire used in the present invention may be either a resin bond wire or an electrodeposited abrasive wire. For example, a wire on which diamond abrasive grains having a grain size of approximately 10 μm to 20 μm are electrodeposited and fixed by Ni plating can be preferably used because of its favorable durability.

Further, the kind of a coolant used in the present invention is also not limited. For example, a water-based coolant or a glycol-based coolant is preferably used. In addition, the glycol may be selected from various kinds of glycols such as poly ethylene glycol, diethylene glycol, and propylene glycol.

As described above, according to the present invention, wear and loss of abrasive grains fixed to a wire surface, and clogging due to machining dust can be effectively inhibited. Therefore, the number of times the wire can be used is increased, and the consumption of wires required for slicing silicon ingots can be significantly reduced.

Further, as described above, the kind of coolant used in the present invention is not limited in particular. When the viscosity of the coolant used is specified to 0.1 mPa·s or more and 100 mPa·s or less, clogging due to machining dust can be more effectively inhibited, and besides, improvement in the product yield can be expected.

If a coolant having high viscosity is used for a bonded abrasive wire saw, the coolant hardly falls from a wire, and a wire of which surface is provided with a thick coolant film is supplied to a portion of a silicon ingot to be sliced. Therefore, the portion of the silicon ingot to be sliced is expanded by the wire more than necessary, which would result in cracks in the wafers to be obtained by the slicing process. Further, use of a high-viscosity coolant for a bonded abrasive wire saw would reduce the effect of expelling machining dust attached to the wire surface. Accordingly, abrasive grains fixed to the wire surface are clogged with the machining dust, which would result in reduced cutting ability of the wire to shorten the life of the wire.

For this reason, in order to reliably avoid the above problem, in the present invention, a coolant having a viscosity of 100 mPa·s or less is preferably used. To the contrary, if the viscosity of the coolant is less than 0.1 mPa·s, the retention of coolant on the bonded abrasive wire is affected, and the effect of expelling machining dust would be reduced. Thus, in the present invention, a coolant having a viscosity of 0.1 mPa·s or more is preferably selected. Note that examples of a coolant having a viscosity of 0.1 mPa·s or more and 100 mPa·s or less may include, for example, a water-based coolant or a glycol-based coolant.

Next, a wire saw of the present invention will be described.

A wire saw of the present invention includes a bonded abrasive wire helically wound at a constant pitch around peripheral surfaces of a plurality of rollers; a first coolant supply means for supplying a coolant onto the wire; a second coolant supply means for supplying the coolant to a side portion of the silicon ingot to be cut where the wire passes in slicing of the silicon ingot.

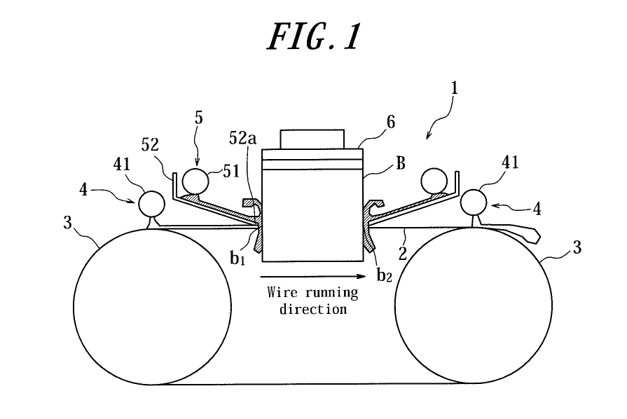

FIG. 1 is a schematic diagram of a main part of a wire saw of the present invention. A wire saw 1 includes a wire supply and take-up means (not shown) for supplying and taking up a wire 2, main rollers 3 spaced a predetermined distance from each other in parallel, a first coolant supply means 4, and a second coolant supply means 5. A plurality of grooves are formed at a constant pitch on surfaces of the main rollers 3, and the wire 2 is wound on those grooves to form a wire array. Above the wire array, a work holder 6 for retaining a silicon ingot B and pressing the silicon ingot B against the wire array is disposed so that it can be moved up and down using an elevating unit not shown. Note that the silicon ingot B in the diagram is retained by the work holder 6 such that the length direction of the silicon ingot B is perpendicular to the plane of paper.

The first coolant supply means 4 includes nozzles 41 disposed above one of the main rollers 3, which serves to cool the wire 2 and the main rollers 3 by supplying a coolant to the wire 2 and the main rollers 3. Note that the longitudinal direction of the nozzles 41 is perpendicular to the plane of paper, and for example, known nozzles such as tubular nozzles each provided with a slit or a plurality of nozzle openings along the longitudinal direction can be employed for the nozzles 41.

The second coolant supply means 5 includes nozzles 51 and guide boards 52, and serves to supply a coolant to side portions b₁ and b₂ of the silicon ingot B to be cut where the wire passes in slicing of the silicon ingot. As with the nozzles 41, the longitudinal direction of the nozzles 51 is perpendicular to the plane of paper, and known nozzles such as tubular nozzles each provided with a slit or a plurality of nozzle openings along the longitudinal direction can be employed for the nozzles 51.

The guide boards 52 disposed under the nozzles 51 are members for guiding the coolant ejected from the nozzles 51 to the side portions b₁ and b₂ of the silicon ingot to be cut. As with the nozzles 41 and the nozzles 51, the longitudinal direction of the guide boards 52 is perpendicular to the plane of paper, and the tips 52a of the guide boards are placed in the vicinity of the side portions b₁ and b₂ of the silicon ingot to be cut so that the coolant ejected from the slits or the nozzle openings of the nozzles 51 is guided to the side portions b₁ and b₂ of the silicon ingot to be cut.

Note that when the nozzles 41, the nozzles 51, and the guide boards 52 are provided such that the sizes of them in the longitudinal direction are longer than the length of the silicon ingot B, the coolant can be supplied uniformly in the longitudinal direction of the silicon ingot B. Further, when the guide boards 52 are provided such that, for example, they can be rotated about axes (not shown) extending in the direction perpendicular to the plane of paper, the coolant can be supplied to desired positions by adjusting the angles of the guide boards 52.

In slicing the silicon ingot B using the wire saw 1 of the present invention, the wire 2 is run by the wire supply and take-up means and the coolant is ejected from the nozzles 41 of the first coolant supply means 4 and the nozzles 51 of the second coolant supply means 5. As mentioned above, different from slurry used for a free abrasive wire saw, working fluid used in the present invention is a coolant having a low viscosity. Therefore, the coolant ejected from the nozzles 41 of the first coolant supply means 4 is sprayed on the wire 2 and the main rollers 3 below. After cooling the wire 2 and the main rollers 3, most of the coolant falls from the wire 2 before reaching the side portions b₁ and b₂ of the silicon ingot to be sliced.

On the other hand, the coolant ejected from the nozzles 51 of the second coolant supply means 5 flows down on the guide boards 52 to be continuously supplied to the side portions b₁ and b₂ of the silicon ingot to be cut. Therefore, the wire saw 1 of the present invention makes it possible to ensure supply of coolant to a portion of the silicon ingot to be sliced. This can sufficiently suppress processing heat due to shortage of coolant supplied, which can be a factor of wear and loss of abrasive grains fixed to the wire surface. Further, the wire saw 1 of the present invention significantly improves the effect of expelling machining dust from the portion to be sliced since the coolant is ensured to be supplied to the side portion b₂ of the silicon ingot to be cut on the side where the wire 2 is wound out.

Consequently, the wire saw 1 of the present invention which has the second coolant supply means 5 provided with the guide boards 52 drastically improves wire life and greatly reduces consumption of the wire required for slicing a silicon ingots, which accordingly helps to reduce the cost of facilities for producing silicon wafers. Further, the guide boards 52 provided on the wire saw 1 of the present invention can greatly reduce the amount of coolant flown down to regions other than the predetermined cut portion, thereby greatly contributing to reduction in the cost of manufacturing silicon wafers. In addition, a given amount of coolant can be reliably and uniformly supplied to desired supply position throughout the length direction of the ingot.

### EXAMPLES

Next, the advantages of the present invention will be described with the use of examples of the present invention and comparative examples. However, the examples of the present invention are only exemplifications for demonstrating the present invention, and do not limit the present invention.

### Example 1

A block silicon single crystal ingot of length: 156 mm, width: 156 mm, and height: 200 mm was sliced into 560 sheets of wafers using a wire saw shown in FIG. 1 while measuring the deflection of the wire in the vicinity of side portions (b₁ and b₂ in FIG. 1) of the silicon ingot to be cut. The processing conditions are shown below.

### <Coolant>

Kind: Diethylene glycol
Viscosity: 10 mPa·s (25° C.)
Supply from first coolant supply means: 50 liter/min
Supply from second coolant supply means: 50 liter/min

### <Wire>

Type: Diamond electrodeposited wire (grain size of diamond: 10 μm to 20 μm)
Running speed: 1000 m/min (the running direction is switched per 40 to 45 seconds)

### Comparative Example 1

A silicon single crystal ingot having the same size as that of the silicon single crystal ingot in Example 1 is sliced using a wire saw shown in FIG. 6 under the same conditions as Example 1, except for the coolant supply means.

### <Coolant>

Coolant supply (nozzles 40 in FIG. 6): 50 liter/min
Coolant supply (nozzles 50 in FIG. 6): 50 liter/min

(Evaluation)

As wear or loss of the abrasive grains, or clogging due to machining dust reduce working performance of a wire, the drag on the wire being run is increased. Accordingly, when the working performance of a wire is reduced, the wire is deflected at side portions (b₁ and b₂ in FIG. 1) of the silicon ingot to be cut, and the deflection increases as the working performance is reduced.

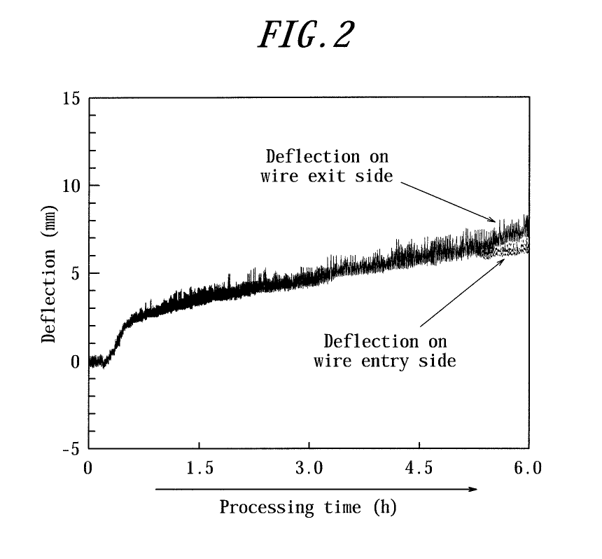

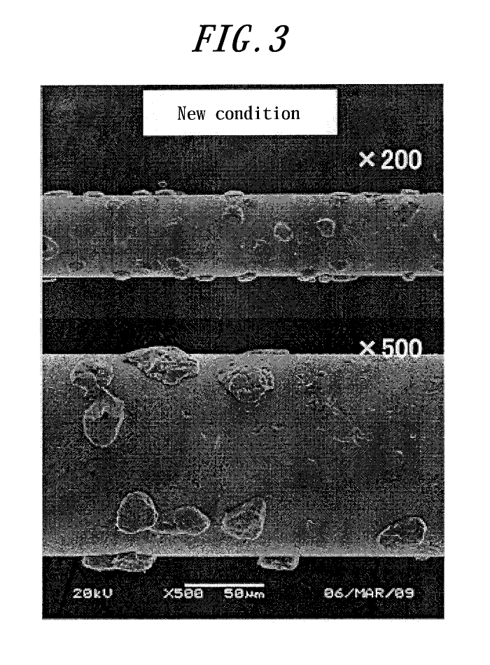

FIG. 2 shows a result of measuring the deflection of the wire in Example 1. As apparent from FIG. 2, in Example 1 in accordance with the conditions of the present invention, the slicing process of the silicon ingot was completed while maintaining a favorable wire running state with the deflection of the wire at the side portions of the silicon ingot to be cut within the range of 8 mm both on the wire entry side (b₁) and the wire exit side (b₂). FIG. 3 shows the wire having been used in Example 1 which was observed by SEM. Very little wear and loss of abrasive grains were found in the used wire and the wire was determined to be reusable.

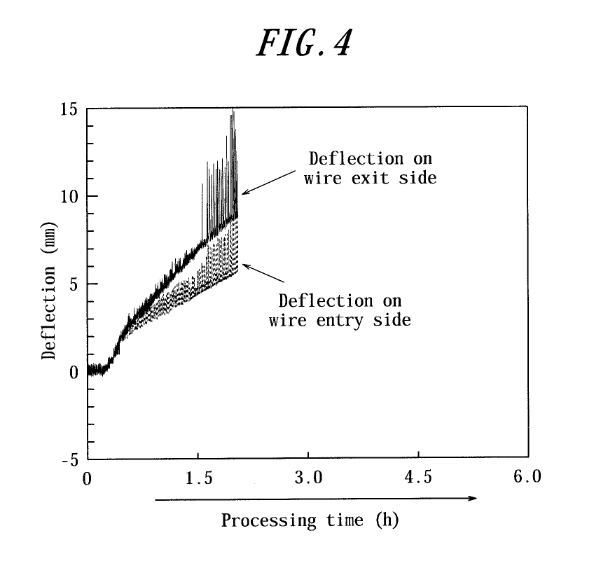

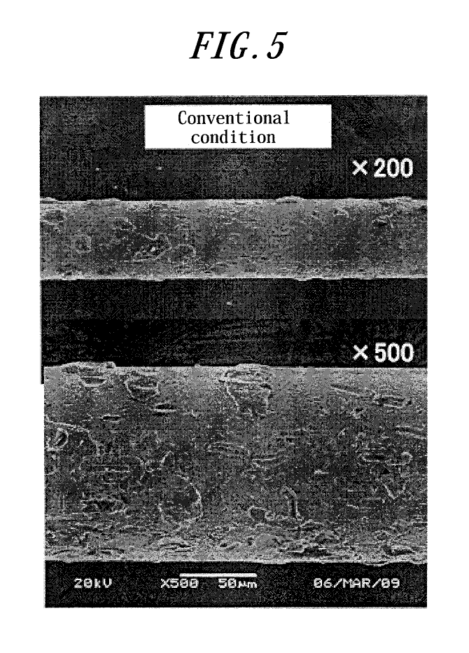

FIG. 4 shows a result of measuring the deflection of the wire in Comparative Example 1. As shown in FIG. 4, the deflection of the wire in Comparative Example 1 at the side portions of the silicon ingot to be cut amounted to 8 mm on the wire entry side (b₁), and to 15 mm on the wire exit side (b₂), and the wire broke in the process of slicing. FIG. 5 shows the wire having been used in Comparative Example 1, which was observed by SEM. Wear and loss of abrasive grains of the used wire were severe and the wire was found to be non-reusable.

### Example 2

A block silicon single crystal ingot of length: 156 mm, width: 156 mm, and height: 150 mm was sliced into 417 sheets of wafers using the wire saw shown in FIG. 1. In slicing, coolants having different viscosities (Levels 1 to 3) as shown in Table 1 were used, and whether wafer cracking or wire breaking had occurred or not was examined. The slicing conditions other than the above conditions are shown below.

### <Coolant>

Supply from first coolant supply means: 50 liter/min
Supply from second coolant supply means: 50 liter/min

### <Wire>

Type: Diamond electrodeposited wire (grain size of diamond: 10 μm to 20 μm)
Running speed: 1000 m/min (the miming direction is switched per 40 to 45 seconds)

(Evaluation)

Incidence of wafer cracking (%) and incidence of wire breaking (%) with respect to each of the viscosities (Levels 1 to 3) of the coolants are shown in Table 1. “Incidence of wafer cracking (%)” and “incidence of breaking of wire (%)” in Table 1 were calculated from the following expressions.

Incidence of wafer cracking(%): number of cracked wafers÷(ingot height÷slice pitch)×100

Incidence of wire breaking(%): number of breaking of wire÷number of slicing×100

In the above expressions, “number of cracked wafers” means the number of wafers cracked among wafers obtained by slicing one ingot. Meanwhile, “number of slicing” refers to the number of ingots subjected to slicing, and a case where a wire is broken while slicing one ingot is counted as “number of breaking of wire=1”.

Note that in this example, “number of slicing=20” was employed for calculating the incidence of wire breaking (%).

TABLE 1

| | Coolant | | | |
|---|---|---|---|---|
| | | Viscosity | Wafer cracking | Wire breaking |
| | Type | (mPa × s) | incidence (%) | incidence (%) |
| Level 1 | Glycol-based | 70-90 | 0.3 | 0 |
| Level 2 | Glycol-based | 110-130 | 3.8 | 5 |
| Level 3 | Oil-based | 200-220 | 15.2 | 20 |

As shown in Table 1, in a case of using the coolant having a viscosity of 200 mPa·s to 220 mPa·s (Level 3) which is equivalent to that of slurry used for a free abrasive wire saw, the incidence of wafer cracking exceeded 15% and the incidence of wire breaking was 20%, which would reduce yield. On the other hand, when the coolant having a viscosity of 70 mPa·s to 90 mPa·s (Level 1) is used, both the incidence of wafer cracking and the incidence of wire breaking was less than 1%; thus, the effect of improving yield can be expected. Also in a case of using the coolant having a viscosity of 110 mPa·s to 130 mPa·s (Level 2), both the incidence of wafer cracking and the incidence of wire breaking were within approximately 5% although inferior to (Level 1). This confirms that slicing using such a coolant can be performed without problem in terms of industrially mass-producing silicon wafers.

### INDUSTRIAL APPLICABILITY

A method of slicing a silicon ingot for slicing a silicon ingot using a bonded abrasive wire saw is provided, which can reduce the consumption of the bonded abrasive wire required for the slicing process as much as possible, thereby greatly reducing the manufacturing cost. A wire saw used for this method is also provided.

### EXPLANATION OF REFERENCE NUMERALS

1: Wire saw
2: Wire
3: Main roller
4: First coolant supply means
41: Nozzle
5: Second coolant supply means
51: Nozzle
52: Guide board
52a: Guide board tip
B: Silicon block

1. A method of slicing a silicon ingot using a wire saw, wherein while a bonded abrasive wire helically wound at a constant pitch around peripheral surfaces of a plurality of rollers is run with a coolant being supplied onto the wire, and while the coolant is also supplied to a side portion of the silicon ingot to be cut where the wire passes in slicing of the silicon ingot; the silicon ingot is moved relative to the wire, thereby slicing the silicon ingot to form a plurality of silicon wafers.

2. The method of slicing a silicon ingot according to claim 1, wherein the coolant has a viscosity of 0.1 mPa·s or more and 100 mPa·s or less.

3. A wire saw comprising:
a bonded abrasive wire helically wound at a constant pitch around peripheral surfaces of a plurality of rollers;
a first coolant supply means for supplying a coolant onto the wire; and
a second coolant supply means provided with a guide board for guiding the coolant to a side portion of the silicon ingot to be cut where the wire passes in slicing of the silicon ingot.
